(19) United States
(12) Patent Application Publication
(10) Pub. No.: US 2024/0332244 A1
(43) Pub. Date: Oct. 3, 2024

(54) METHODS OF PROCESSING A SUBSTRATE ON A BONDING SYSTEM, AND RELATED BONDING SYSTEMS

(71) Applicant: KULICKE AND SOFFA INDUSTRIES, INC., Fort Washington, PA (US)

(72) Inventors: Thomas J. Colosimo, JR., West Chester, PA (US); Adeel Ahmad Bajwa, Blue Bell, PA (US); Michael P. Schmidt-Lange, North Wales, PA (US)

(73) Assignee: KULICKE AND SOFFA INDUSTRIES, INC., Fort Washington, PA (US)

(21) Appl. No.: 18/610,434

(22) Filed: Mar. 20, 2024

Related U.S. Application Data
(60) Provisional application No. 63/456,724, filed on Apr. 3, 2023.

(51) Int. Cl. H01L 23/00

(52) U.S. Cl. CPC H01L 24/75; H01L 24/81; H01L 2224/7501; H01L 2224/81011

(57) ABSTRACT

A method of processing a substrate on a bonding system is provided. The method includes: (a) providing an oxide reduction delivery system on a bonding system; (b) supporting a substrate on a support structure of the bonding system; and (c) moving at least one of the oxide reduction delivery system and the support structure with respect to one another, such that a gas provided by the oxide reduction delivery system contacts the substrate.

### CROSS REFERENCE TO RELATED APPLICATION

This application claims the benefit of U.S. Provisional Application No. 63/456,724, filed Apr. 3, 2023, the content of which is incorporated herein by reference.

### FIELD

The invention relates to bonding systems and processes (such as flip chip, thermocompression, and thermosonic bonding systems and processes), and more particularly, to improved methods of processing substrates on such bonding systems.

### BACKGROUND

Traditional semiconductor packaging typically involves die attach processes and wire bonding processes. Advanced semiconductor packaging technologies (e.g., flip chip bonding, thermocompression bonding, etc.) continue to gain traction in the industry. For example, in thermocompression bonding (i.e., TCB), heat and/or pressure (and sometimes ultrasonic energy) are used to form a plurality of interconnections between (i) electrically conductive structures on a semiconductor element and (ii) electrically conductive structures on a substrate.

In certain flip chip bonding or thermocompression bonding applications, the electrically conductive structures of the semiconductor element and/or the substrate may include structures made of a material that is subject to oxidation and/or other contamination (e.g., copper pillars). In such applications, it is desirable to provide an environment suitable for bonding. For example, such an environment may be provided by using a reducing gas at the bonding area to reduce potential oxidation and/or contamination of the electrically conductive structures of the semiconductor element or the substrate to which it will be bonded. Example patents and patent applications related to such a reducing gas environment include: U.S. Pat. No. 10,861,820 (entitled “METHODS OF BONDING SEMICONDUCTOR ELEMENTS TO A SUBSTRATE, INCLUDING USE OF A REDUCING GAS, AND RELATED BONDING MACHINES”); U.S. Pat. No. 11,205,633 (entitled “METHODS OF BONDING OF SEMICONDUCTOR ELEMENTS TO SUBSTRATES, AND RELATED BONDING SYSTEMS”); U.S. Pat. No. 11,515,286 (entitled “METHODS OF BONDING OF SEMICONDUCTOR ELEMENTS TO SUBSTRATES, AND RELATED BONDING SYSTEMS”); U.S. Patent Application Publication No. 2023/0133526 (entitled “BONDING SYSTEMS FOR BONDING OF SEMICONDUCTOR ELEMENTS TO SUBSTRATES, AND RELATED METHODS”); U.S. Patent Application Publication No. 2023/0260953 (entitled “METHODS OF MONITORING GAS BYPRODUCTS OF A BONDING SYSTEM, AND RELATED MONITORING SYSTEMS AND BONDING SYSTEMS”); U.S. Patent Application Publication No. 2023/0326903 (entitled “BONDING SYSTEMS, AND METHODS OF PROVIDING A REDUCING GAS ON A BONDING SYSTEM”); and U.S. Patent Application Publication No. 2024/0063169 (entitled “BONDING SYSTEMS FOR BONDING A SEMICONDUCTOR ELEMENT TO A SUBSTRATE, AND RELATED METHODS”). These references are incorporated by reference herein in their entirety.

Other conventional techniques for providing such a suitable environment include use of a plasma gas delivery system or delivery of a gas including attached electrons.

It would be desirable to provide improved methods of processing substrates (e.g., reducing oxides on conductive structures of such substrates) in connection with the bonding of semiconductor elements to a substrate, and related bonding systems.

### SUMMARY

According to an exemplary embodiment of the invention, a method of processing a substrate on a bonding system is provided. The method includes: (a) providing an oxide reduction delivery system on a bonding system; (b) supporting a substrate on a support structure of the bonding system; and (c) moving at least one of the oxide reduction delivery system and the support structure with respect to one another, such that a gas provided by the oxide reduction delivery system contacts the substrate.

According to other embodiments of the invention, the method recited in the immediately preceding paragraph may have any one or more of the following features: the oxide reduction delivery system is integrated with a bond head assembly of the bonding system; the oxide reduction delivery system is a reducing gas delivery system; the oxide reduction delivery system is a formic acid vapor delivery system; the oxide reduction delivery system is a plasma gas delivery system; the oxide reduction delivery system is configured to deliver the gas including attached electrons; step (c) includes moving the oxide reduction delivery system with respect to the support structure while the gas is dispensed by the oxide reduction delivery system; step (c) includes moving the support structure with respect to the oxide reduction delivery system while the gas is dispensed by the oxide reduction delivery system; and/or step (c) includes moving the oxide reduction delivery system along a first motion axis while dispensing the gas and moving the support structure along a second motion axis while the gas is dispensed by the oxide reduction delivery system.

According to another exemplary embodiment of the invention, another method of processing a substrate on a bonding system is provided. The method includes: (a) providing an oxide reduction delivery system integrated with a bond head assembly of a bonding system; (b) supporting a substrate on a support structure of the bonding system; and (c) moving the oxide reduction delivery system with respect to the support structure such that a gas provided by the oxide reduction delivery system contacts the substrate.

According to other embodiments of the invention, the method recited in the immediately preceding paragraph may have any one or more of the following features: the oxide reduction delivery system is a reducing gas delivery system; the oxide reduction delivery system is a formic acid vapor delivery system; the oxide reduction delivery system is a plasma gas delivery system; the oxide reduction delivery system is configured to deliver the gas including attached electrons; and/or step (c) includes moving the oxide reduction delivery system by moving the bond head assembly according to a predetermined motion profile.

According to yet another exemplary embodiment of the invention, a bonding system is provided. The bonding system includes: a bond head assembly configured for bonding a semiconductor element to a substrate; an oxide reduction delivery system; and a support structure configured for supporting the substrate. At least one of the oxide reduction delivery system and the support structure is configured to move with respect to the other, such that a gas provided by the oxide reduction delivery system contacts the substrate.

According to other embodiments of the invention, the method recited in the immediately preceding paragraph may have any one or more of the following features: the oxide reduction delivery system is integrated with the bond head assembly; the oxide reduction delivery system is a reducing gas delivery system; the oxide reduction delivery system is a formic acid vapor delivery system; the oxide reduction delivery system is a plasma gas delivery system; the oxide reduction delivery system is configured to deliver the gas including attached electrons; the oxide reduction delivery system is configured to move with respect to the support structure while the gas is dispensed by the oxide reduction delivery system; the support structure is configured to move with respect to the oxide reduction delivery system while the gas is dispensed by the oxide reduction delivery system; and/or the oxide reduction delivery system is configured to move along a first motion axis while dispensing the gas, and the support structure is configured to move along a second motion axis.

According to yet another exemplary embodiment of the invention, a method of operating a bonding system is provided. The method includes the steps of: (a) providing an oxide reduction delivery system on the bonding system; (b) supporting a substrate on a support structure of the bonding system; (c) distributing a gas provided by the oxide reduction delivery system to contact the substrate; and (d) storing information related to portions of the substrate that are processed during step (c).

According to other embodiments of the invention, the method recited in the immediately preceding paragraph may have any one or more of the following features: step (c) includes moving at least one of the oxide reduction delivery system and the support structure with respect to one another, such that the gas contacts portions of the substrate during the step of moving; step (d) includes storing information related to a time when ones of the portions of the substrate are processed during step (c); step (d) includes storing information related to which portions of the substrate have been processed during step (c), and which portions of the substrate have not been processed during step (c); step (d) includes storing information related to which portions of the substrate have been adequately processed during step (c) based on predetermined criteria; step (d) includes determining if processing of a first portion of the substrate during step (c) results in adequate processing of a second portion of the substrate because of exposure to the gas during the processing of the first portion of the substrate; a step of providing a schedule of bonding semiconductor elements to the substrate using the information stored in step (d); providing the schedule of bonding the semiconductor elements may include providing a schedule of processing portions of the substrate in connection with the bonding of the semiconductor elements to the substrate; a step of determining if a specific portion of the substrate has been adequately processed using the information stored in step (d); a step of bonding a semiconductor element to the specific portion of the substrate determined to have been adequately processed; and/or a step of distributing the gas to contact the specific portion of the substrate determined to not have been adequately processed, and then bonding a semiconductor element to the specific portion of the substrate.

### BRIEF DESCRIPTION OF THE DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIGS. 1A-1E are block diagram side views illustrating a bonding system for bonding a die to a substrate in accordance with an exemplary embodiment of the invention;

FIGS. 2A-2D are block diagram side views illustrating another bonding system for bonding a die to a substrate in accordance with another exemplary embodiment of the invention;

FIGS. 3A-3D are block diagram side views illustrating a method of processing a substrate on the bonding system of FIGS. 1A-1E in accordance with an exemplary embodiment of the invention;

FIGS. 4A-4D are block diagram side views illustrating another method of processing a substrate on the bonding system of FIGS. 1A-1E in accordance with another exemplary embodiment of the invention;

FIGS. 5A-5C are block diagram top views of the bonding system of FIGS. 1A-1E, illustrating yet another method of processing a substrate on a bonding system, in accordance with yet another exemplary embodiment of the invention;

FIGS. 6A-6G are block diagram top views of the bonding system of FIGS. 1A-1E, illustrating yet another method of processing a substrate on a bonding system, in accordance with yet another exemplary embodiment of the invention;

FIG. 7 is a flow diagram illustrating a method of processing a substrate in accordance with an exemplary embodiment of the invention; and

FIG. 8 is a flow diagram illustrating a method of processing a substrate on a bonding system in accordance with an exemplary embodiment of the invention.

### DETAILED DESCRIPTION

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, a semiconductor chip, a semiconductor wafer, a BGA substrate, a semiconductor element, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “substrate” is intended to refer to any structure to which a semiconductor element may be bonded. Exemplary substrates include, for example, a leadframe, a PCB, a carrier, a module, a semiconductor chip, a semiconductor wafer, a BGA substrate, another semiconductor element, etc.

As used herein, the term “gas” is intended to be broadly construed. In accordance with certain exemplary embodiments of the invention, fluxless bonding systems use oxide reduction delivery systems for providing a “gas” for reducing oxides on conductive structures of a substrate and/or a semiconductor element. Such a gas may include a carrier gas (e.g., nitrogen, argon, etc.), where such carrier gas may be a mixture of gases (e.g., nitrogen and hydrogen mix, etc.). For example, the gas may be a reducing gas (e.g., formic acid vapor, acetic acid vapor), a plasma gas (e.g., including a carrier gas such as nitrogen), a gas including attached electrons (e.g., including a carrier gas such as a nitrogen and hydrogen mix), etc. The bonding system may be, for example, a flip chip bonding system, a thermocompression bonding system, a thermosonic bonding system, etc.

In connection with bonding systems, the processing (e.g., cleaning) of substrates may be accomplished according to certain embodiments of the invention (e.g., a cleaning of substrates to reduce oxides on conductive structures of the substrates) (e.g., where the cleaning may be performed according to a predetermined schedule such as a periodic cleaning, a planned cleaning according to a planned bonding process, etc.). In certain embodiments, an oxide reduction delivery system (e.g., a bond head shroud) may be integrated with a bond head assembly. The oxide reduction delivery system may be moved (e.g., “scanned”) across a substrate surface while a gas (e.g., a reducing gas) is applied in order to process (e.g., clean) the surface of the substrate. In certain embodiments, a gas micro-environment (e.g., a reducing gas environment) may be established on a surface of a substrate.

As provided above, the oxide reduction delivery system may be integrated with a bond head assembly of the bonding system such that movement of the bond head assembly is used to perform the movement of the oxide reduction delivery system. Alternatively, the oxide reduction delivery system may be integrated with (e.g., coupled to, etc.) another motion system (e.g., an optical motion system) of the bonding system such that movement via the another motion system is used to perform the movement of the oxide reduction delivery system. In another alternative, the oxide reduction delivery system may include its own motions system.

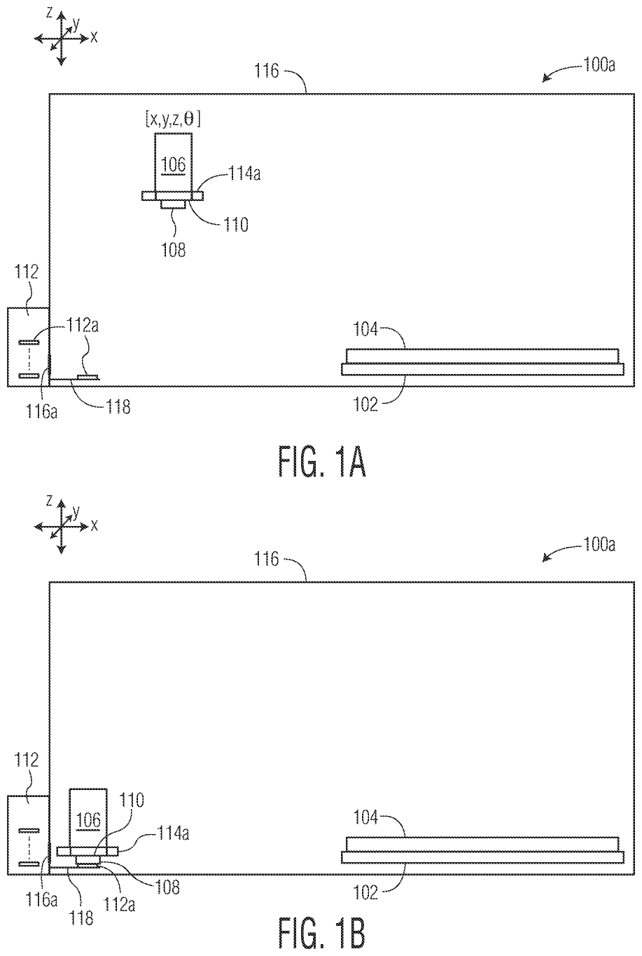

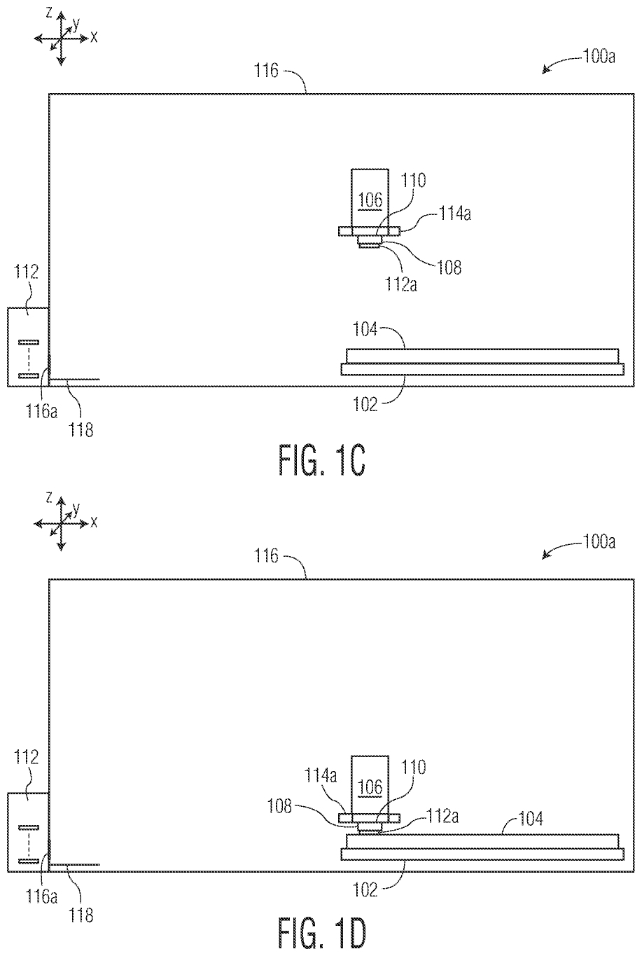

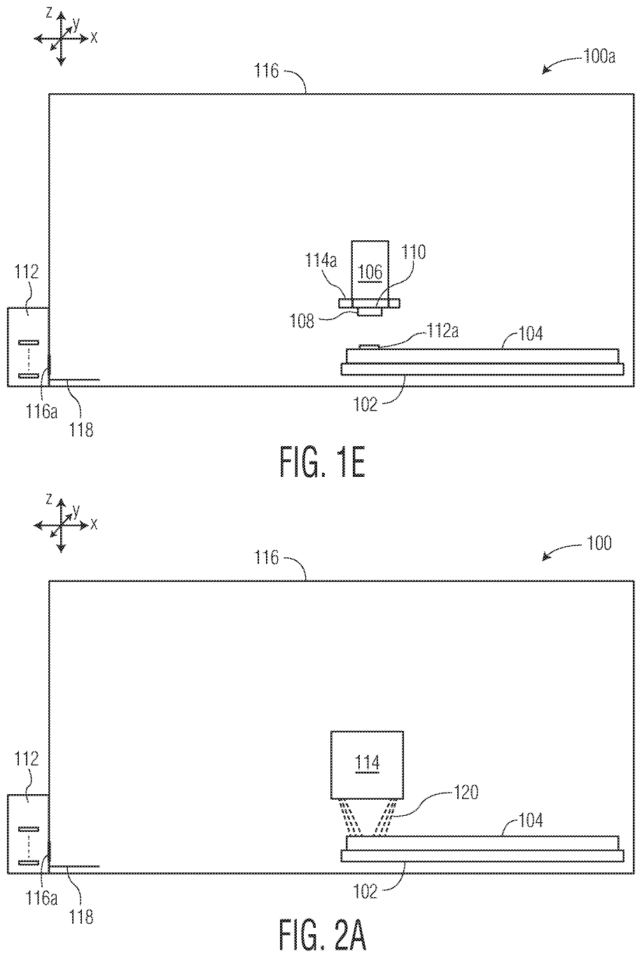

Referring now to FIGS. 1A-1E, a bonding system 100a for processing a substrate 104 is illustrated. Bonding system 100a is configured for bonding a die 112a to substrate 104. Bonding system 100a includes a bond head assembly 106, which may be configured to move along (and about) one or more of a plurality of axes of bonding system 100a (e.g., the x-axis, y-axis, z-axis, theta (rotative) axis, etc.). Bond head assembly 106 includes (and/or carries) a heater 110 and a bonding tool 108. In certain bonding machines (e.g., thermocompression bonding machines) it may be desirable to heat bonding tool 108. While FIGS. 1A-1E illustrate a separate heater 110 for heating bonding tool 108 (for heating die 112a), it will be appreciated that heater 110 and bonding tool 108 may be integrated into a single element (e.g., a heated bonding tool).

Bonding system 100a is illustrated including a support structure 102 configured to support substrate 104. Support structure 102 may be configured to move along one or more of a plurality of axes of bonding system 100a (e.g., the x-axis, y-axis, z-axis, etc.).

Bonding system 100a is illustrated including (or using) a die source 112. It will be appreciated by those skilled in the art that any type of semiconductor element supply may be substituted for die source 112 in the various drawings. Die source 112 is configured to provide die 112a (or other semiconductor element) through a door 116a of a chamber 116 and to a pickup structure 118 (e.g., a shelf). In connection with a bonding operation, die 112a can be picked up (e.g., using bonding tool 108) from pickup structure 118, carried by bond head assembly 106, and bonded to substrate 104 (e.g., using bonding tool 108). In the various embodiments provided herein, it will be appreciated that chamber 116 is provided with an inert environment (e.g., a nitrogen environment) in order to inhibit and/or prevent oxidation of conductive structures in chamber 116.

Referring specifically to FIG. 1A, die 112a is illustrated having been supplied to pickup structure 118 by die source 112. In FIG. 1B, bond head assembly 106 is illustrated making contact with die 112a via bonding tool 108. In FIG. 1C, bond head assembly 106 is illustrated carrying die 112a (e.g., along the x-axis) to a position near a bonding location of substrate 104. In FIG. 1D, bond head assembly 106 is illustrated placing and bonding die 112a to substrate 104 (via bonding tool 108) at a bonding location. In FIG. 1E, bond head assembly 106 is illustrated moving away (e.g., along the z-axis) from now-bonded die 112a.

In certain bonding applications (e.g., thermocompression bonding, flip chip bonding, etc.), it may be desirable to provide an environment suitable for bonding. Such an environment can be provided by using a gas (e.g., a reducing gas, a plasma gas, a gas including attached electrons, etc.) at the bonding area to reduce potential oxides of substrate 104 prior to (or concurrent with) a bonding operation. A reducing gas may be delivered (or supplied) to the bonding area by an oxide reduction delivery system 114. In certain embodiments, oxide reduction delivery system 114 may be integrated with bond head assembly 106 (of a bonding system). In certain embodiments, oxide reduction delivery system 114 may be a reducing gas delivery system to distribute gas or fluids to the bonding area. An oxide reduction delivery system (e.g., a reducing gas delivery system) may include any appropriate structure to distribute gas or fluids, such as a manifold, a pipe (or tube) opening, a nozzle, a sprayer, etc.

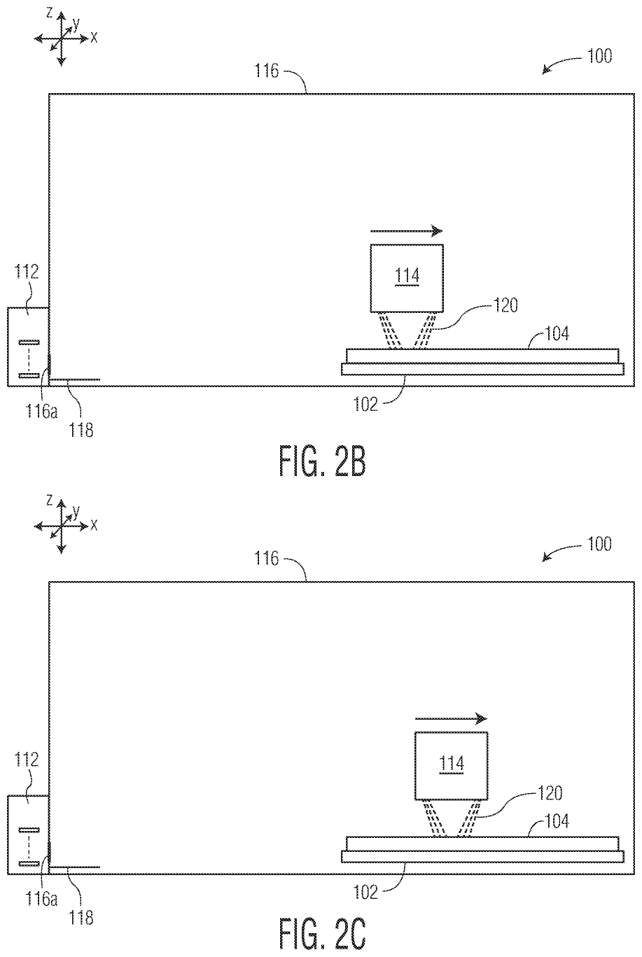

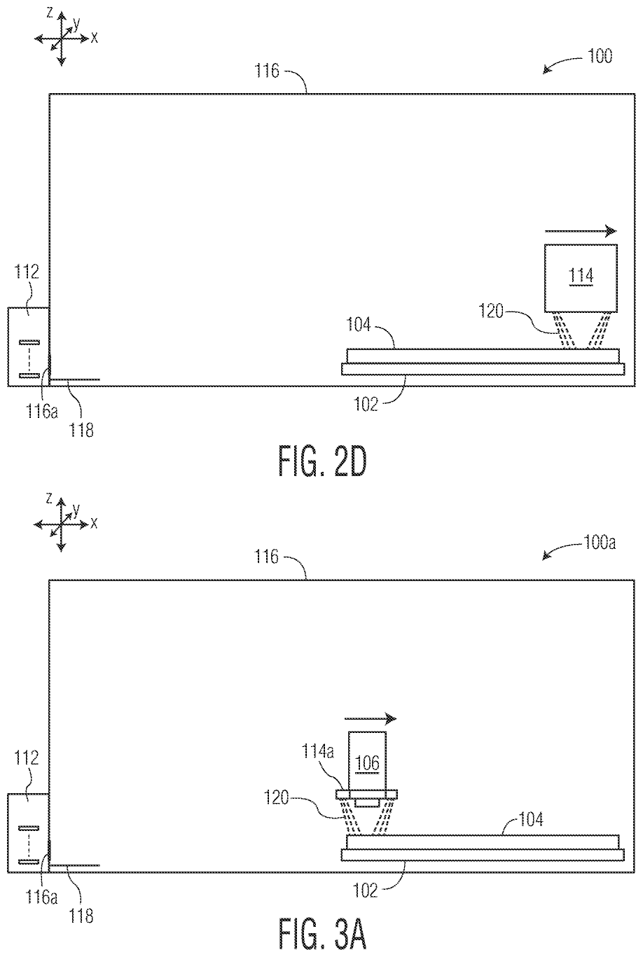

Referring now to FIGS. 2A-2D, a bonding system 100 for processing a substrate 104 is illustrated. Bonding system 100 is illustrated processing (e.g., cleaning, treating, etc.) a surface of substrate 104. Bonding system 100 is substantially similar to bonding system 100a of FIGS. 1A-1E, where like elements use the same reference numerals. Accordingly, the description of bonding system 100a is applicable to bonding system 100, unless indicated otherwise.

In FIGS. 2A-2D, bonding system 100 is illustrated including an oxide reduction delivery system 114 (in lieu of bond head assembly 106 including integrated oxide reduction delivery system 114a, heater 110, and bonding tool 108 as shown in FIGS. 1A-1E). It shall be understood by those skilled in the art that bonding system 100 includes a bond head assembly, and a bonding tool-although not expressly illustrated. Oxide reduction delivery system 114 may be any system for providing a gas for reducing oxides at the bonding area. In certain embodiments, oxide reduction delivery system 114 may be an integrated oxide reduction delivery system 114a (as described in connection with FIGS. 1A-1E), or it may be an oxide reduction delivery system that is independent (e.g., separate from the bond head assembly). In certain embodiments, oxide reduction delivery system 114 may be a formic acid vapor delivery system. In certain embodiments, oxide reduction delivery system 114 may be configured to deliver a gas that includes attached electrons. In certain embodiments, oxide reduction delivery system 114 may be configured to supply a plasma gas to reduce or remove oxides (e.g., on substrate 104). For example, oxide reduction delivery system 114 may be a plasma gas delivery system.

Referring now to FIG. 2A, oxide reduction delivery system 114 is illustrated providing gas 120 at a first location, such that gas 120 contacts substrate 104. In FIG. 2B, oxide reduction delivery system 114 is illustrated having moved horizontally (e.g., along the x-axis) (e.g., continuously moving, intermittently moving, moving along a predetermined motion profile, etc.). Oxide reduction delivery system 114 is illustrated providing gas 120 (e.g., continuously, intermittently, etc.) that contacts substrate 104 at a second location. In FIG. 2C, oxide reduction delivery system 114 is illustrated having further moved horizontally (e.g., along the x-axis). Oxide reduction delivery system 114 is illustrated providing gas 120 (e.g., continuously, intermittently, etc.) that contacts substrate 104 at a third location. In FIG. 2D, oxide reduction delivery system 114 is illustrated having moved further horizontally (e.g., along the x-axis) such that it provides gas 120 (e.g., continuously, intermittently, etc.) that contacts substrate 104 at another location. Oxide reduction delivery system 114 may provide a continuous flow of gas 120 as it moves across substrate 104 or it may provide a flow of gas 120 only in designated locations of substrate 104.

In FIGS. 2A-2D, oxide reduction delivery system 114 is illustrated moving with respect to substrate 104 and support structure 102, where oxide reduction delivery system 114 moves (e.g., with respect to a reference point on bonding system 100) and substrate 104 and support structure 102 remain in place. However, the invention is not so limited. For example, support structure 102 may be configured to move along a plurality of axes of bonding system 100 (e.g., the x-axis, y-axis, z-axis, etc.) and oxide reduction delivery system 114 may remain in place (e.g., in at least one axis). Support structure 102 can thus move with respect to the oxide reduction delivery system 114, while oxide reduction delivery system 114 dispenses gas 120. Similarly, oxide reduction delivery system 114 may be configured to move along (and about) a plurality of axes of bonding system 100 (e.g., the x-axis, y-axis, z-axis, theta (rotative) axis, etc.). In certain embodiments, oxide reduction delivery system 114 can move along a first motion axis (e.g., the y-axis) while dispensing gas 120, and support structure 102 can move along a second motion axis (e.g., the x-axis) while oxide reduction delivery system 114 dispenses gas 120.

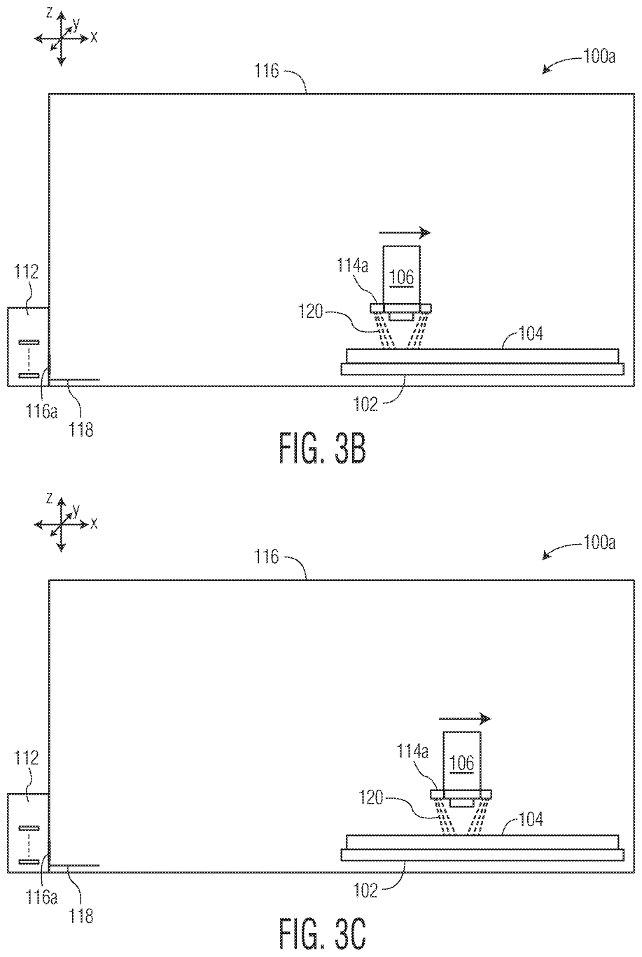

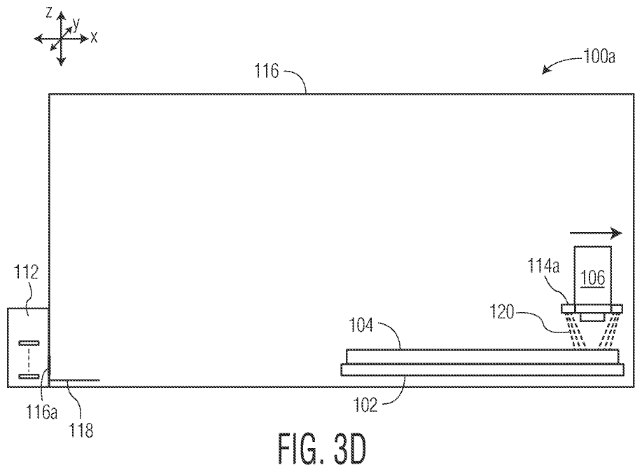

Referring now to FIGS. 3A-3D, bonding system 100a (previously illustrated and described in connection with FIGS. 1A-1E) for processing substrate 104 is illustrated. Bonding system 100a is illustrated processing (e.g., cleaning, treating, etc.) a surface of substrate 104. In FIG. 3A, oxide reduction delivery system 114a is illustrated providing gas 120 at a first location, such that gas 120 contacts substrate 104. In FIG. 3B, oxide reduction delivery system 114a is illustrated having moved horizontally (e.g., along the x-axis). Oxide reduction delivery system 114a is illustrated providing gas 120 (e.g., continuously, intermittently, etc.) that contacts substrate 104 at a second location. In FIG. 3C, oxide reduction delivery system 114a is illustrated having further moved horizontally (e.g., along the x-axis). Oxide reduction delivery system 114a is illustrated providing gas 120 that contacts substrate 104 at a third location. In FIG. 3D, oxide reduction delivery system 114a is illustrated having moved further horizontally (e.g., along the x-axis) such that it provides gas 120 that contacts substrate 104 at another location.

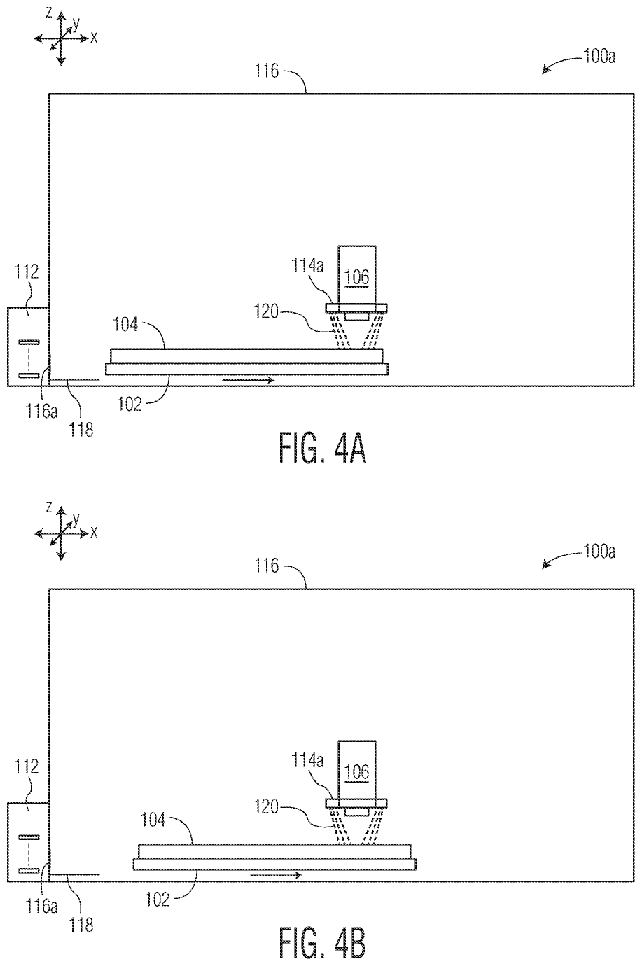

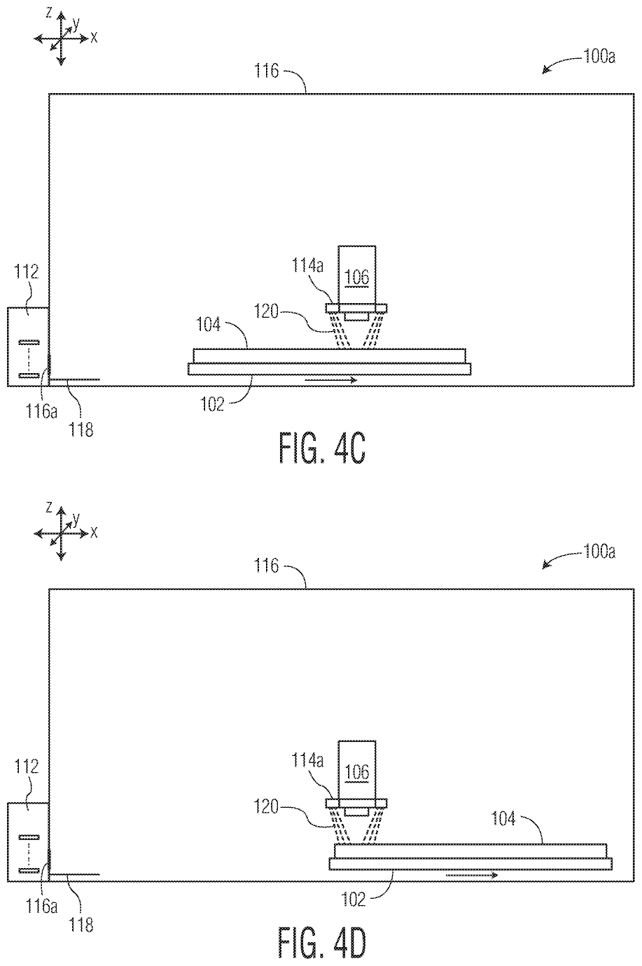

Referring now to FIGS. 4A-4D, bonding system 100a (previously illustrated and described in connection with FIGS. 1A-1E) for processing substrate 104 is again illustrated. Bonding system 100a is illustrated processing (e.g., cleaning, treating, etc.) a surface of substrate 104. In FIG. 4A, oxide reduction delivery system 114a is illustrated providing gas 120 to a first location, such that gas 120 contacts substrate 104. In FIG. 4B, support structure 102 is illustrated having moved horizontally (e.g., along the x-axis) (e.g., continuously moving, intermittently moving, moving according to a predetermined motion profile, etc.). Oxide reduction delivery system 114a is illustrated providing gas 120 (e.g., continuously, intermittently, etc.) that contacts substrate 104 at a second location. In FIG. 4C, support structure 102 is illustrated having further moved horizontally (e.g., along the x-axis). Oxide reduction delivery system 114a is illustrated providing gas 120 that contacts substrate 104 at a third location. In FIG. 4D, support structure 102 is illustrated having moved further horizontally (e.g., along the x-axis) such that oxide reduction delivery system 114a provides gas 120 that contacts substrate 104 at another location.

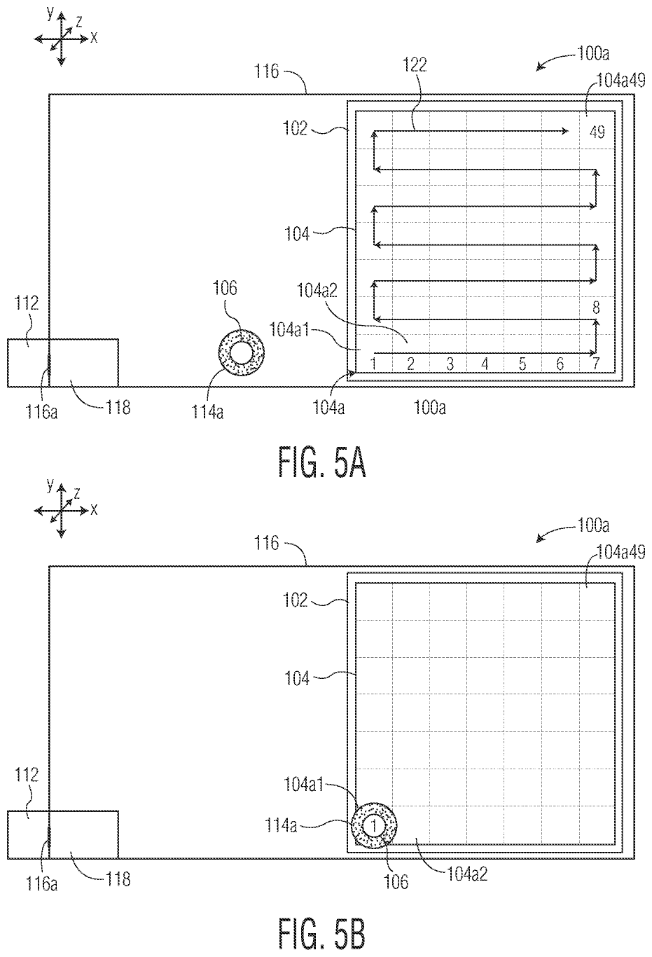

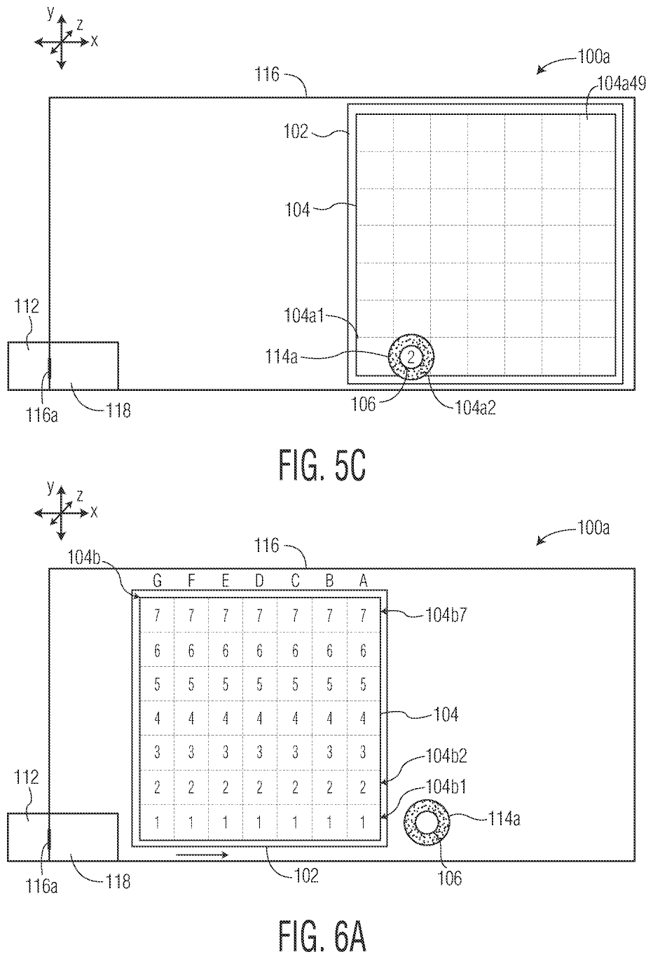

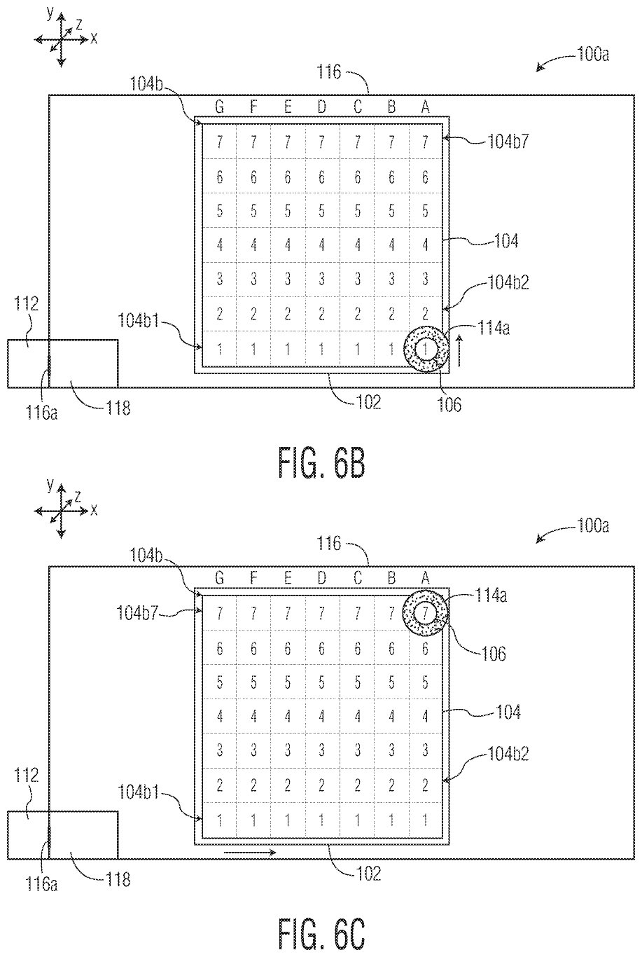

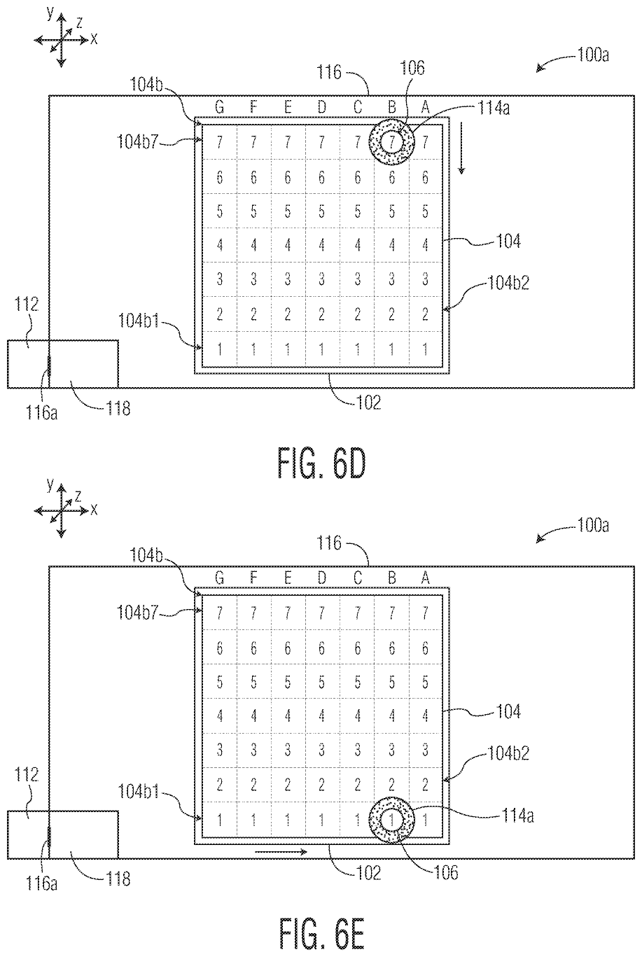

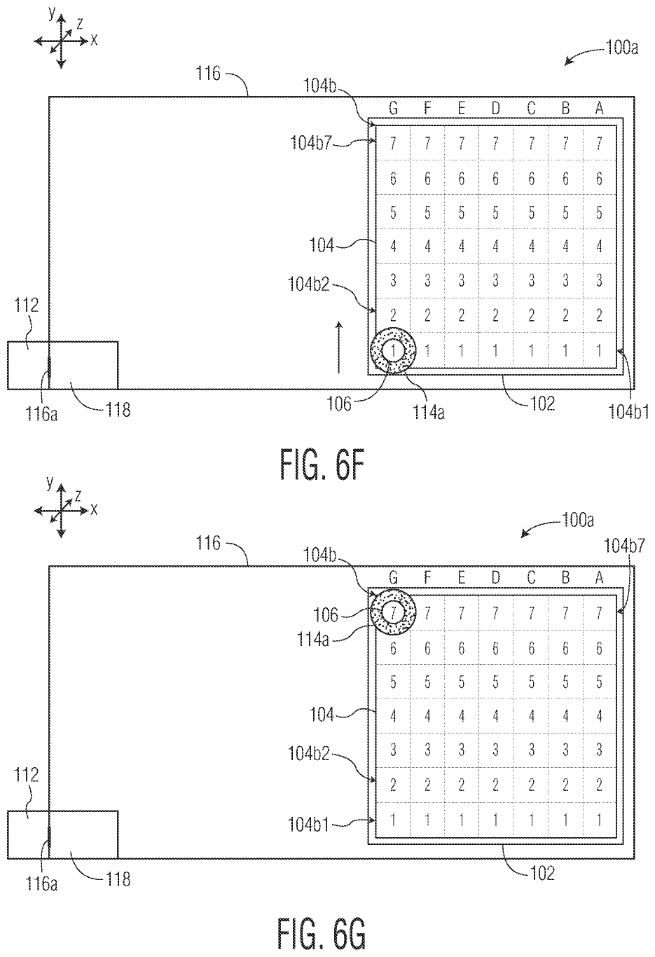

While FIGS. 2A-2D, FIGS. 3A-3D, and FIGS. 4A-4D illustrate a simple path for processing a substrate while dispensing a gas (e.g., an oxide reduction delivery system moving in a single-axis linear path, a support structure moving along a simple linear path, etc.), the invention is not limited thereto. Any type of movement of an oxide reduction delivery system and/or a support structure is contemplated within the scope of the invention. FIGS. 5A-5C illustrate a more complex exemplary predetermined motion profile of oxide reduction delivery system 114a for processing (e.g., cleaning) substrate 104. FIGS. 6A-6G illustrate combined motion of oxide reduction delivery system 114a and support structure 102 in the processing (e.g., cleaning) of substrate 104 along an exemplary predetermined motion profile. Of course, other alternative motion paths are contemplated.

Referring specifically to FIGS. 5A-5C, top views of bonding system 100a of FIGS. 1A-1E are illustrated. A processing area 104a of a top surface of substrate 104 is illustrated, including a plurality of processing locations (e.g., 104a1, 104a2, . . . , 104a49). In FIG. 5A, bond head assembly 106 (along with oxide reduction delivery system 114a) is illustrated away from substrate 104. In FIG. 5B, bond head assembly 106 (along with oxide reduction delivery system 114a) is illustrated directly above substrate 104 at processing location 104a1. At this location, gas 120 (not labelled in FIGS. 5A-5C, but see gas 120 in above described figures) is provided to processing location 104a1. In FIG. 5C, bond head assembly 106 (along with oxide reduction delivery system 114a) is illustrated directly above substrate 104 at processing location 104a2. At this location, gas 120 is provided to processing location 104a2. This process is repeated for each of the plurality of processing locations (e.g., 104a1, 104a2, . . . , 104a49) along path 122 (see FIG. 5A). In certain embodiments, bond head assembly 106 and oxide reduction delivery system 114a are moved continuously across processing area 104a of substrate 104. In certain embodiments, bond head assembly 106 and oxide reduction delivery system 114a are moved (e.g., indexed) to discrete positions across processing area 104a of substrate 104 at discrete times. In certain embodiments, the dwell time (i.e., the time gas 120 is provided to each processing location) may be configured such that sufficient processing occurs (e.g., where a predicted quantity or monitored quantity of oxides are removed or reduced).

Referring now to FIGS. 6A-6G, top views of bonding system 100a of FIGS. 1A-1E are illustrated. A processing area 104b of a top surface of substrate 104 is illustrated, labeled as a plurality of processing rows (e.g., 104b1, 104b2, . . . , 104b7) and a plurality of processing columns (e.g., indicated by “A”, “B”, “C”, “D”, “E”, “F”, and “G”).

In FIG. 6A, bond head assembly 106 (with oxide reduction delivery system 114a) are illustrated prior to a processing step (and away from substrate 104). Support structure 102 is illustrated moving along the x-axis (as indicated by the arrow).

In FIG. 6B, bond head assembly 106 (with oxide reduction delivery system 114a) is illustrated directly above substrate 104 at a first processing location (located at a processing row 104b1 in a processing column indicated by the “A”) and during a processing step, where gas 120 (not illustrated) is provided. Bond head assembly 106 (with oxide reduction delivery system 114a) is illustrated moving along the y-axis (as indicated by the arrow).

In FIG. 6C, bond head assembly 106 (with oxide reduction delivery system 114a) is illustrated at another processing location (located at a processing row 104b7 in a processing column indicated by the “A”). Support structure 102 is now illustrated moving along the x-axis.

In FIG. 6D, because support structure 102 has indexed along the x-axis, bond head assembly 106 (with oxide reduction delivery system 114a) is illustrated at yet another processing location (located at a processing row 104b7 in a processing column indicated by the “B”). Bond head assembly 106 (with oxide reduction delivery system 114a) is now illustrated moving along the y-axis.

In FIG. 6E, bond head assembly 106 (with oxide reduction delivery system 114a) is now illustrated at yet another processing location (located at a processing row 104b1 in a processing column indicated by the “B”). Support structure 102 is now illustrated moving along the x-axis.

In FIG. 6F, bond head assembly 106 (with oxide reduction delivery system 114a) is illustrated at yet another processing location (located at a processing row 104b1 in a processing column indicated by the “G”). Bond head assembly 106 (with oxide reduction delivery system 114a) is illustrated moving along the y-axis, to complete the processing of column “G”. Oxide reduction delivery system 114a provides gas 120 (not illustrated) in each of FIGS. 6B-6F.

At FIG. 6G, bond head assembly 106 (with oxide reduction delivery system 114a) has now reached another processing location (located at a processing row 104b7 in a processing column indicated by the “G”). Oxide reduction delivery system 114a may stop providing gas 120 at this point. This process of dispensing gas 120, while moving at least one of oxide reduction delivery system 114a (e.g., by movement of bond head assembly 106) and support structure 102, may continue until all processing areas have been processed (e.g., cleaned).

Each of FIGS. 3A-3D, FIGS. 4A-4D, FIGS. 5A-5C and FIGS. 6A-6G illustrate processing of a substrate (e.g., removing oxides from the substrate) using an integrated oxide reduction delivery system (e.g., integrated with a bond head assembly), the invention is not limited to such embodiments. For example, an oxide reduction delivery system that is not integrated with a bond head assembly may be used to process the substrate (e.g., see description of FIGS. 2A-2D above).

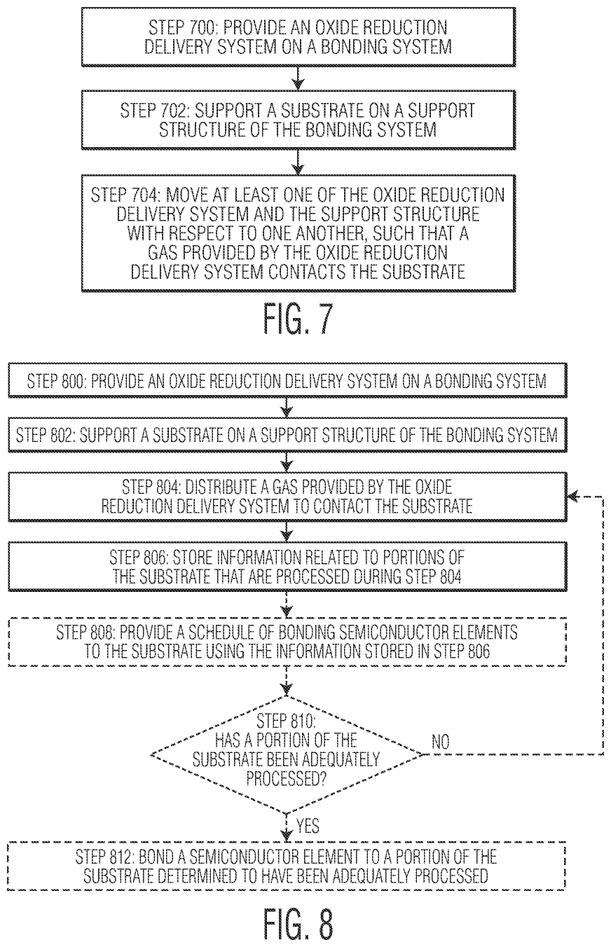

FIG. 7 and FIG. 8 are flow diagrams in accordance with certain exemplary embodiments of the invention. As is understood by those skilled in the art, certain steps included in the flow diagram may be omitted; certain additional steps may be added; and the order of the steps may be altered from the order illustrated.

FIG. 7 is a flow diagram illustrating a method of processing a substrate on a bonding system. At Step 700, an oxide reduction delivery system (e.g., oxide reduction delivery system 114, oxide reduction delivery system 114a, etc.) is provided on a bonding system (e.g., bonding system 100, bonding system 100a, etc.). At Step 702, a substrate (e.g., substrate 104) is supported on a support structure (e.g., support structure 102) of the bonding system.

At Step 704, at least one of the oxide reduction delivery system and the support structure are moved with respect to one another, such that a gas (e.g., gas 120) provided by the oxide reduction delivery system contacts the substrate. For example, the oxide reduction delivery system can move and the support structure can remain stationary (e.g., see FIGS. 2A-2D and 3A-3D). In another example, the support structure can move and the oxide reduction delivery system can remain stationary (e.g., see FIGS. 4A-4D). In another example, the oxide reduction delivery system and the support structure can both move with respect to each other (e.g., simultaneously, intermittently, at discrete intervals, in indexed positions, etc.).

As will be appreciated by those skilled in the art, although the drawings illustrate a die source 112 (including a plurality of semiconductor die 112a), the invention relates to bonding systems configured for bonding any type of semiconductor element.

Although the present invention has been described primarily with respect to processing operations (e.g., cleaning of substrates to reduce oxides on conductive structures of the substrates) on a bonding system, it is understood that the invention includes such processing operations in connection with bonding operations. For example, the processing (e.g., cleaning) of a substrate may be completed, and then a plurality of semiconductor elements may be bonded to the substrate (e.g., see the bonding process of FIGS. 1A-1E). In another example, the bonding of a substrate (e.g., bonding semiconductor elements to the substrate) may be interrupted in order to process a part of the substrate, and then the bonding of the substrate (e.g., bonding semiconductor elements to the substrate) may resume on the bonding system.

It will be appreciated by those skilled in the art that the actual implementation of the invention may be more complex than the examples shown in the drawings, and illustrated herein. For example, factors may be considered before implementing a method of processing (e.g., cleaning) a substrate, and/or bonding semiconductor elements to the substrate. Units per hour (i.e., UPH), sometimes referred to as “throughput”, is an important consideration. Another consideration is the time that has elapsed after a portion of the substrate is processed (e.g., after some time, it may be important to re-process the substrate by cleaning). Yet another consideration is the effect of processing a first portion of the substrate on other portions of the substrate (e.g., spraying one portion may provide cleaning of an adjacent portion of the substrate). These and other considerations are explored in the exemplary flow diagram shown in FIG. 8.

FIG. 8 is a flow diagram illustrating a method of processing a substrate on a bonding system. At Step 800, an oxide reduction delivery system is provided on the bonding system (e.g., oxide reduction delivery system 114 of FIGS. 2A-2D, oxide reduction delivery system 114a of FIGS. 1A-1E and other drawings herein, etc.). At Step 802, a substrate is supported on a support structure of the bonding system (e.g., substrate 104 supported by support structure 102). At Step 804, a gas provided by the oxide reduction delivery system is distributed to contact the substrate (e.g., where the gas is a formic acid vapor, a plasma gas, a gas including attached electrons, etc.). At Step 806, information related to portions of the substrate that are processed during step (c) are stored. Exemplary information that may be stored includes information related to the time of processing of ones of the portions of the substrate, which portions of the substrate have been processed (and when they were processed), which portions have not been processed, etc. Information may also include which portions of the substrate have been adequately processed based on predetermined criteria (e.g., timing of last processing of the portion of the substrate, proximity in space and time to a processed portion of the substrate, parameters related to distribution of the gas such as chemical composition and flow rate, etc.).

At optional Step 808, a schedule of bonding semiconductor elements to the substrate using the information stored in step 806 is provided (e.g., wherein the schedule is at least partially determined by the predetermined criteria used in Step 806). Such as schedule may be automatically generated using a computer included in, or accessible to, the relevant bonding system. Step 808 may also include providing a schedule of processing portions of the substrate in connection with the bonding of the semiconductor elements to the substrate (e.g., process a portion of the substrate, bond elements to that portion of the substrate, process another portion of the substrate, bond elements to that another portion of the substrate, etc.). At Optional Step 810, a determination is made as to whether a specific portion of the substrate has been adequately processed using the information stored in Step 804. At Optional Step 812, a semiconductor element is bonded to the specific portion of the substrate determined to have been adequately processed. However, if the specific portion of the substrate is determined to have not been adequately processed, Step 804 is repeated (where the gas may be distributed to the specific portion of the substrate), and then the semiconductor element is bonded to the specific portion of the substrate.

Although the invention is illustrated and described herein with reference to specific embodiments, the invention is not intended to be limited to the details shown. Rather, various modifications may be made in the details within the scope and range of equivalents of the claims and without departing from the invention.

1. A method of processing a substrate on a bonding system, the method comprising the steps of:
(a) providing an oxide reduction delivery system on the bonding system;
(b) supporting the substrate on a support structure of the bonding system; and
(c) moving at least one of the oxide reduction delivery system and the support structure with respect to one another, such that a gas provided by the oxide reduction delivery system contacts the substrate.

2. The method of claim 1 wherein the oxide reduction delivery system is integrated with a bond head assembly of the bonding system.

3. The method of claim 1 wherein the oxide reduction delivery system is a reducing gas delivery system.

4. The method of claim 1 wherein the oxide reduction delivery system is a formic acid vapor delivery system.

5. The method of claim 1 wherein the oxide reduction delivery system is a plasma gas delivery system.

6. The method of claim 1 wherein the oxide reduction delivery system is configured to deliver the gas including attached electrons.

7. The method of claim 1 wherein step (c) includes moving the oxide reduction delivery system with respect to the support structure while the gas is dispensed by the oxide reduction delivery system.

8. The method of claim 1 wherein step (c) includes moving the support structure with respect to the oxide reduction delivery system while the gas is dispensed by the oxide reduction delivery system.

9. The method of claim 1 wherein step (c) includes moving the oxide reduction delivery system along a first motion axis while dispensing the gas and moving the support structure along a second motion axis while the gas is dispensed by the oxide reduction delivery system.

10. A method of processing a substrate on a bonding system, the method comprising the steps of:
(a) providing an oxide reduction delivery system integrated with a bond head assembly of the bonding system;
(b) supporting the substrate on a support structure of the bonding system; and
(c) moving the oxide reduction delivery system with respect to the support structure such that a gas provided by the oxide reduction delivery system contacts the substrate.

11. The method of claim 10 wherein the oxide reduction delivery system is a reducing gas delivery system.

12. The method of claim 10 wherein the oxide reduction delivery system is a formic acid vapor delivery system.

13. The method of claim 10 wherein the oxide reduction delivery system is a plasma gas delivery system.

14. The method of claim 10 wherein the oxide reduction delivery system is configured to deliver the gas including attached electrons.

15. The method of claim 10 wherein step (c) includes moving the oxide reduction delivery system by moving the bond head assembly according to a predetermined motion profile.

16. The method of claim 10 further comprising the step of (d) moving the support structure with respect to the oxide reduction delivery system while the gas is dispensed by the oxide reduction delivery system.

17. A bonding system comprising:
a bond head assembly configured for bonding a semiconductor element to a substrate;
an oxide reduction delivery system; and
a support structure configured for supporting the substrate,
wherein at least one of the oxide reduction delivery system and the support structure is configured to move with respect to the other, such that a gas provided by the oxide reduction delivery system contacts the substrate.

18. The bonding system of claim 17 wherein the oxide reduction delivery system is integrated with the bond head assembly.

19. The bonding system of claim 17 wherein the oxide reduction delivery system is a reducing gas delivery system.

20. The bonding system of claim 17 wherein the oxide reduction delivery system is a formic acid vapor delivery system.

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)
